(19) United States
(12) Patent Application Publication
(10) Pub. No.: US 2025/0250683 A1
(43) Pub. Date: Aug. 7, 2025

(54) ETCHING COMPOSITION, METHOD OF ETCHING METAL-CONTAINING LAYER BY USING THE SAME, AND METHOD OF MANUFACTURING SEMICONDUCTOR DEVICE BY USING THE ETCHING COMPOSITION

(71) Applicant: Samsung Electronics Co., Ltd., Suwon-si (KR)

(72) Inventors: Kyuyoung HWANG, Suwon-si (KR); Byungjoon KANG, Suwon-si (KR); Daihyun KIM, Suwon-si (KR); Sungmin KIM, Suwon-si (KR); Jina KIM, Suwon-si (KR); Mihyun PARK, Suwon-si (KR); Insun PARK, Suwon-si (KR); Jungmin OH, Suwon-si (KR); Kum Hee LEE, Suwon-si (KR); Cheol HAM, Suwon-si (KR)

(73) Assignee: Samsung Electronics Co., Ltd., Suwon-si (KR)

(21) Appl. No.: 19/020,348

(22) Filed: Jan. 14, 2025

(30) Foreign Application Priority Data
Feb. 5, 2024 (KR) 10-2024-0017691

(51) Int. Cl. C23F 1/32; H01L 21/306

(52) U.S. Cl. CPC C23F 1/32; H01L 21/30604

(57) ABSTRACT

An etching composition may include an oxidizing agent, an accelerator, an ammonium salt, and an aqueous solvent, wherein the accelerator may include one or more compounds represented by Formula 1, and the ammonium salt may include at least one compound having a structure in which at least one of hydrogen ions (H⁺) of a hydroxyl group (*—OH) or a thiol group (*—SH) included in the accelerator is substituted with an ammonium cation (NH₄⁺):

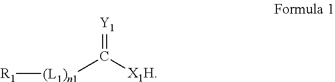

Formula 1 is as described in the present specification.

### CROSS-REFERENCE TO RELATED APPLICATION

This application is based on and claims priority under 35 U.S.C. § 119 to Korean Patent Application No. 10-2024-0017691, filed on Feb. 5, 2024, in the Korean Intellectual Property Office, the disclosure of which is incorporated by reference herein in its entirety.

### BACKGROUND

### 1. Field

The disclosure relates to an etching composition, a method of etching a metal-containing layer by using the same, and a method of manufacturing a semiconductor device by using the etching composition.

### 2. Description of the Related Art

To fulfill the high performance and low prices demanded by consumers, semiconductor devices need to be more integrated and more reliable. As the degree of integration of semiconductor devices is increased, damage to components of a semiconductor device during the manufacturing process may have a greater impact on the reliability and electrical characteristics of a semiconductor device. In particular, in the process of manufacturing a semiconductor device, various etching processes may be performed on a certain layer (for example, a metal-containing layer). In order to perform a more effective etching process, there is a continuing need for etch compositions that can provide good etch rates, good etch selectivity to adjacent layers, no surface residue after etching, and good storage stability.

### SUMMARY

Provided is an etching composition that has more effectively controlled etching selectivity and etch rate for a metal-containing layer, which is a to-be-etched layer, and at the same time has excellent high-temperature stability.

Additional aspects will be set forth in part in the description which follows and, in part, will be apparent from the description, or may be learned by practice of the presented embodiments of the disclosure.

According to an example embodiment of the present disclosure, an etching composition may include an oxidizing agent, an accelerator, an ammonium salt, and an aqueous solvent, wherein the accelerator may include one or more compounds represented by Formula 1 below, and the ammonium salt may include at least compound having a structure in which at least one of the hydrogen ions (H⁺) of a hydroxyl group (*—OH) or a thiol group (*—SH) included in the accelerator is substituted with an ammonium cation (NH₄⁺).

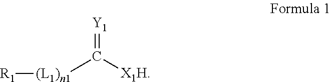

In Formula 1,
X₁ and Y₁ may each independently be O or S,
L₁ may be a single bond, a cyclic group having 2 to 10 carbon atoms unsubstituted or substituted with at least one R₀, *—C(R₁₁)(R₁₂)—**′, *—C(═O)—**′, *—C(═S)—**′, *—N(R₁₁)—**′, *—O—**′, or *—S—**′,
n1 may be an integer from 1 to 50,
when n1 is 2 or more, two or more of L₁ may be the same or different from each other,
R₁, R₁₁, R₁₂ and R₀ may each independently be:
   hydrogen, deuterium, *—F, *—Cl, *—Br, *—I, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), or *—NH—C(═S)—(NH₂), or
   a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with deuterium, *—F, *—Cl, *—Br, *—I, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), *—NH—C(═S)—(NH₂), or any combination thereof, and
when a second carbon directly bonded to a first carbon to which a hydroxyl group is bonded exists in Formula 1, a hydroxyl group (*—OH) and a thiol group (*—SH) are not bonded to the second carbon, and
when a fourth carbon directly bonded to a third carbon to which a thiol group is bonded in exists in Formula 1, a hydroxyl group (*—OH) and a thiol group (*—SH) are not bonded to the fourth carbon.

According to an example embodiment of the present disclosure, a method of etching a metal-containing layer may include preparing a substrate provided with a metal-containing layer thereon, and performing an etching process on the metal-containing layer using the etching composition to remove at least a portion of the metal-containing layer.

In some embodiments, the metal-containing layer may include a first region and a second region. The performing the etching process on the metal-containing layer may include etching at least a portion of the first region of the metal-containing layer at a first etch rate using the etching composition and etching at least a portion of the second region of the metal-containing layer at a second etch rate using the etching composition, and the second etch rate is greater than the first etch rate.

According to example embodiment of the present disclosure, a method of manufacturing a semiconductor device may include preparing a substrate including a metal-containing layer thereon, performing an etching process on the metal-containing layer using the etching composition to remove at least a portion of the metal-containing layer, and performing one or more subsequent manufacturing process(es) to manufacture the semiconductor device.

### BRIEF DESCRIPTION OF THE DRAWINGS

The above and other aspects, features, and advantages of certain embodiments will be more apparent from the following description taken in conjunction with the accompanying drawings, in which:

FIG. 1 illustrates a process flow diagram of an embodiment of a method of manufacturing a semiconductor device; and

FIGS. 2 and 3 are diagrams briefly explaining an embodiment of a method of etching a metal-containing layer.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

### To-be-Etched Layer

The to-be-etched layer may include a metal-containing layer.

Accordingly, the etching composition may be used in an etching process and/or chemical mechanical polishing (CMP) process for the metal-containing layer.

Metal contained in the metal-containing layer may include an alkali metal (for example, sodium (Na), potassium (K), rubidium (Rb), cesium (Cs), etc.), an alkaline earth metal (for example, beryllium (Be), magnesium (Mg), calcium (Ca), strontium (Sr), barium (Ba), etc.), a lanthanum group metal (for example, lanthanum (La), europium (Eu), terbium (Tb), ytterbium (Yb), etc.), a transition metal (for example, scandium (Sc), yttrium (Y), titanium (Ti), zirconium (Zr), hafnium (Hf), vanadium (V), niobium (Nb), tantalum (Ta), chromium (Cr), molybdenum (Mo), tungsten (W), manganese (Mn), iron (Fe), ruthenium (Ru), osmium (Os), cobalt (Co), rhodium (Rh), nickel (Ni), copper (Cu), silver (Ag), zinc (Zn), etc.), post-transition metal (for example, aluminum (Al), gallium (Ga), indium (In), thallium (TI), tin (Sn), bismuth (Bi), etc.), or any combination thereof.

According to an embodiment, the metal-containing layer may include indium (In), titanium (Ti), aluminum (Al), copper (Cu), tungsten (W), cobalt (Co), lanthanum (La), scandium (Sc), gallium (Ga), zinc (Zn), hafnium (Hf), molybdenum (Mo), or any combination thereof.

In some embodiments, the metal-containing layer may include indium (In), titanium (Ti), aluminum (Al), tungsten (W), lanthanum (La), scandium (Sc), gallium (Ga), zinc (Zn), hafnium (Hf), molybdenum (Mo), or any combination thereof.

For example, the metal-containing layer may include aluminum, titanium, lanthanum, tungsten, molybdenum, or any combination thereof.

In some embodiments, the metal-containing layer may include titanium.

In some embodiments, the metal-containing layer may include titanium and aluminum.

The metal-containing layer may include metal, metal nitride, metal oxide, metal oxynitride, or any combination thereof.

The metal-containing layer may include metal, metal nitride, metal oxide, metal oxynitride, or any combination thereof, and the metal contained in each of the metal, metal nitride, metal oxide, and metal oxynitride may include indium (In), titanium (Ti), aluminum (Al), lanthanum (La), scandium (Sc), gallium (Ga), zinc (Zn), hafnium (Hf), or any combination thereof.

The metal-containing layer may include metal nitride. The metal included in the metal nitride may include indium, titanium, aluminum, lanthanum, scandium, gallium, zinc, hafnium, or any combination thereof.

In some embodiments, the metal-containing layer may include titanium nitride. The titanium nitride may further include indium, aluminum, lanthanum, scandium, gallium, hafnium, zinc, or any combination thereof. In some embodiments, the metal-containing layer may include titanium nitride (TiN), titanium nitride further including aluminum (for example, titanium aluminum nitride or TiAlN), titanium nitride further including lanthanum, etc.

In some embodiments, the metal-containing layer may include metal oxide. The metal included in the metal oxide may include titanium, aluminum, lanthanum, scandium, gallium, hafnium, or any combination thereof. For example, the metal-containing layer may include aluminum oxide (for example, Al₂O₃), indium gallium zinc oxide (IGZO), etc.

In some embodiments, the metal-containing layer may include the metal and the metal nitride.

In some embodiments, the metal-containing layer may include, in addition to metal, metalloids (for example, boron (B), silicon (Si), germanium (Ge), arsenic (As), antimony (Sb), and tellurium. (Te), etc.), non-metals (for example, nitrogen (N), phosphorus (P), oxygen (O), sulfur(S), selenium (Se), etc.), and any combination thereof.

For example, the metal-containing layer may further include silicon oxide.

The metal-containing layer may have a single-layer structure including one or more types of materials, or a multi-layer structure or three-dimensional pattern structure including different materials.

According to an embodiment, the metal-containing layer includes a first region and a second region, and a second etch rate at which the etching composition etches the second region may be greater than a first etch rate at which the etching composition etches the first region. During the etching process and/or polishing process for the metal-containing layer, at least a portion of the first region and at least a portion of the second region may be in contact with the etching composition, and since the second etch rate is greater than the first etch rate, the second region may be etched faster than the first region.

For example, the first region may include metal, metal oxide (for example, aluminum oxide), silicon oxide, or any combination thereof.

According to an embodiment, the first region may include aluminum oxide.

In some embodiments, the second region may include metal nitride.

In some embodiments, the second region may include i) titanium nitride (TiN), ii) titanium nitride further including indium, aluminum, lanthanum, scandium, gallium, zinc, hafnium, or any combination thereof (for example, TiAlN), or iii) any combination thereof.

In some embodiments, the first region and the second region may each include i) titanium nitride, ii) titanium nitride further including indium, aluminum, lanthanum, scandium, gallium, zinc, hafnium, or any combination thereof (for example, TiAlN), or iii) any combination thereof.

In some embodiments, the first region may include aluminum, and the second region may not include aluminum.

In some embodiments, the first region may include aluminum oxide, and the second region may include i) titanium nitride (TiN), ii) titanium nitride further including indium, aluminum, lanthanum, scandium, gallium, zinc, hafnium, or any combination thereof (for example, TiAlN), or iii) any combination thereof.

In some embodiments, the first region may include aluminum oxide, and the second region may include titanium nitride (TiN), titanium nitride further including aluminum (TiAlN), or any combination thereof.

In some embodiments, the first region may include an aluminum oxide layer, and the second region may include a titanium nitride layer (TiN layer), a titanium nitride layer further including aluminum (for example, a titanium aluminum nitride layer, or TiAlN layer), or any combination thereof.

In some embodiments, the first region may be an aluminum oxide layer, and the second region may be a titanium nitride layer (TiN layer) or a titanium nitride layer further including aluminum (for example, a titanium aluminum nitride layer or a TiAlN layer).

In some embodiments, the first region may include titanium nitride further including aluminum (for example, TiAlN), and the second region may include titanium nitride (TiN).

In some embodiments, the first region may include a titanium nitride layer further including aluminum (for example, a TiAlN layer), and the second region may include titanium nitride layer (TiN layer).

In some embodiments, the first region may be a titanium nitride layer further including aluminum (for example, TiAlN layer), and the second region may be a titanium nitride layer (TiN layer).

The wording “a layer is etched” as used herein may refer to the feature in which at least some of the materials constituting the layer are removed.

### Etching Composition

The etching composition may include an oxidizing agent, an accelerator, an ammonium salt, and an aqueous solvent.

The etching composition may be used in the etching process and/or CMP process of the to-be-etched layer, for example, a metal-containing layer described herein.

According to an embodiment, the etching composition may consist of the oxidizing agent, the accelerator, the ammonium salt, and the aqueous solvent.

### Oxidizing Agent

The oxidizing agent may etch the metal-containing layer and may include, for example, hydrogen peroxide.

The amount (weight) of the oxidizing agent may be, for example, about 1 wt % to about 50 wt %, about 5 wt % to about 30 wt %, about 10 wt % to about 25 wt %, or about 15 wt % to about 25 wt %, based on 100 wt % of the etching composition.

### Aqueous Solvent

The aqueous solvent is clearly distinguished from various organic solvents and may include, for example, water (for example, deionized water).

According to an embodiment, the aqueous solvent may be water.

In some embodiments, the etching composition may not include an organic solvent.

### Accelerator

The accelerator may promote etching of the metal-containing layer by chelating with metal atoms in the metal-containing layer.

The accelerator may include at least one of compounds represented by Formula 1. For example, the accelerator may include one type of compound of the compounds represented by Formula 1 below:

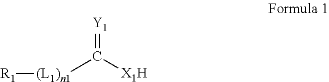

wherein X₁ and Y₁ in Formula 1 may each independently be O or S.

For example, each of X₁ and Y₁ may be O.
L₁ in Formula 1 may be a single bond, a cyclic group having 2 to 10 carbon atoms unsubstituted or substituted with at least one R₀, *—C(R₁₁)(R₁₂)—**′, *—C(═O)—**′, *—C(═S)—**′, *—N(R₁₁)—**′, *—O—**′ or *—S—**′.

n1 in Formula 1 represents the number of L₁, and n1 may be an integer from 1 to 50. When n1 is 2 or more, two or more of L₁ may be the same or different from each other. For example, n1 may be 1 to 40, 1 to 30, 1 to 20, or 1 to 10.

According to an embodiment, in Formula 1, L₁ may be a cyclic group having 2 to 10 carbon atoms unsubstituted or substituted with at least one R₀, and n1 may be 1.

In some embodiments, L₁ in Formula 1 may be a saturated or unsaturated 5-membered to saturated or unsaturated 8-membered carbocyclic group having 5 to 8 carbon atoms, or a saturated or unsaturated 5-membered to saturated or unsaturated 8-membered heterocyclic group having 2 to 7 carbon atoms, each unsubstituted or substituted with at least one R₀.

In some embodiments, L₁ in Formula 1 may be a cyclopentane group, a cyclohexane group, a cycloheptane group, a cyclooctane group, a cyclopentene group, a cyclohexene group, a cycloheptene group, a cyclooctene group, a cyclopentadiene group, a benzene group, a cycloheptadiene group, a cyclooctadiene group, a pyrrolidine group, a tetrahydrofuran group, a tetrahydrothiophene group, a piperidine group, a tetrahydro-2H-pyran group, a tetrahydro-2H-thiopyran group, an azepane group, an oxepane group, a thiepane group, a 2,3-dihydro-1H-pyrrole group, a 2,3-dihydrofuran group, a 2,3-dihydrothiophene group, a 2,5-dihydro-1H-pyrrole group, a 2,5-dihydrofuran group, a 2,5-dihydrothiophene group, a pyrrole group, a furan group, a thiophene group, a pyridine group, a pyrimidine group, a pyrazine group, a pyridazine group, or a triazine group, each unsubstituted or substituted with at least one R₀.

In some embodiments, in Formula 1, L₁ may be a single bond, *—C(R₁₁)(R₁₂)—*′, *—C(═O)—**′, *—C(═S)—**′, *—N(R₁₁)—**′, *—O—**′, or *—S—*′, and n1 may be an integer from 1 to 20. For example, in Formula 1,
i) L₁ may be a single bond, or
ii) L₁ may be *—C(R₁₁)(R₁₂)—**′, or
iii) at least one of n1 L₁ may each independently be *—C(═O)—**′, *—C(═S)—**′, *—N(R₁₁)—**′, *—O—*′, and *—S—**′.

R₁, R₁₁, R₁₂ and R₀ in Formula 1 may each independently be:
hydrogen, deuterium, *—F, *—Cl, *—Br, *—I, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), or *—NH—C(═S)—(NH₂); or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group (for example, a C₁-C₁₀ alkyl group, a C₁-C₁₀ alkoxy group, a phenyl group, a naphthyl group, a pyridinyl group, etc.), each unsubstituted or substituted with deuterium, *—F, *—Cl, *—Br, *—I, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), *—NH—C(═S)—(NH₂), or any combination thereof. R₀ may not be a hydrogen.

For example, R₁, R₁₁, R₁₂, and R₀ may each independently be:
hydrogen, *—F, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), or *—C(═S)—(NH₂); or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group (for example, a C₁-C₁₀ alkyl group, a C₁-C₁₀ alkoxy group, a phenyl group, a naphthyl group, or a pyridinyl group, etc.), each unsubstituted or substituted with *—F, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), or any combination thereof.

In Formula 1,
ii) in the case where a second carbon directly bonded to a first carbon to which a hydroxyl group is bonded exists in Formula 1, a hydroxyl group (*—OH) and a thiol group (*—SH) are not bonded to the second carbon, and
i) in the case where a fourth carbon directly bonded to a third carbon to which a thiol group is bonded exists in Formula 1, a hydroxyl group (*—OH) and a thiol group (*—SH) are not bonded to the fourth carbon.

Accordingly, the cyclometallated ring, which can be formed by chelating the accelerator with the metal atom of the metal-containing layer, may not become a 5-membered cyclometallated ring in which the metal atom of the metal-containing layer is bonded to an oxygen atom or a sulfur atom. Therefore, the etch rate ratio of the metal-containing layer can be more effectively controlled.

According to an embodiment, the compound represented by Formula 1 may include one of compounds represented by Formulae 11 to 19, or any combination thereof:

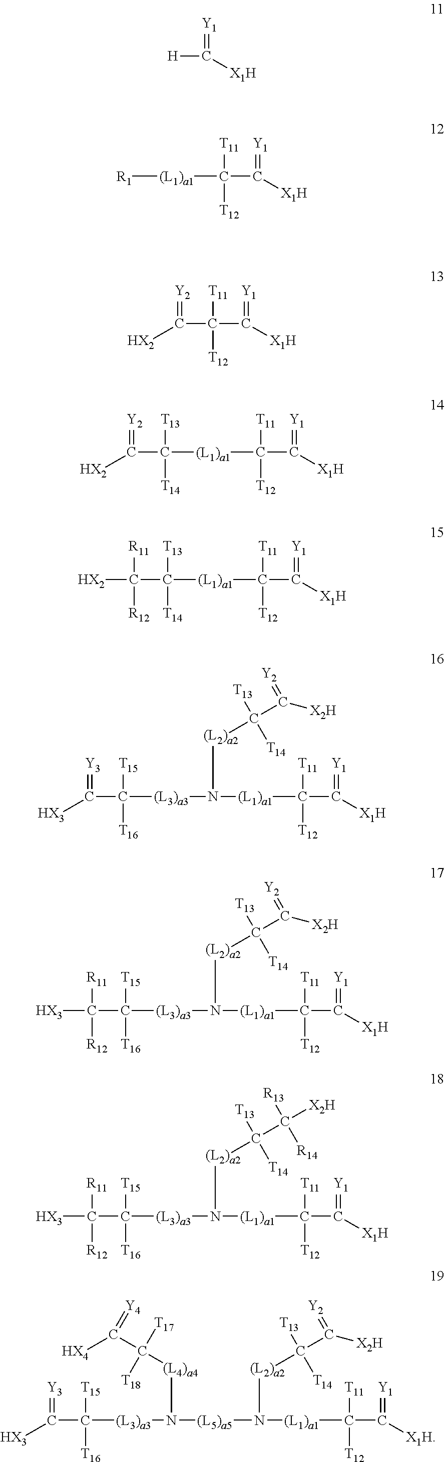

In Formulae 11 to 19,
the description of each of X₁, Y₁, L₁, R₁, R₁₁ and R₁₂ is the same as the description of each of X₁, Y₁, L₁, R₁, R₁₁, and R₁₂ in Formula 1 of this specification, X₂, Y₂, X₃, Y₃, X₄, and Y₄ may each independently be O or S,
the description of each of L₂ to L₅ is the same as the description of L₁ of Formula 1 in this specification,
a1 to a5 may each independently be an integer from 1 to 15,
the description of each of R₁₃ and R₁₄ is the same as the description of R₁₁ in Formula 1 in this specification, and
the description of each of T₁₁ to T₁₈ is the same as the description of R₁₁ of Formula 1 in this specification, but each of T₁₁ to T₁₈ is not a hydroxyl group or a thiol group.

For example, in formulae 11 to 19,

L₁ to L₅ may each independently be a single bond, *—C(R₁₁)(R₁₂)—*′, *—C(═O)—**′, —C(═S)—**′, *—N(R₁₁)—**′, *—O—*′, or *—S—*′).

T₁₁ to T₁₈ may each independently be:
hydrogen, *—F, or *—NH₂; or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with *—F, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), or any combination thereof.

According to an embodiment, the compound represented by Formula 1 may include one of compounds represented by Formulae 110 to 129, or any combination thereof:

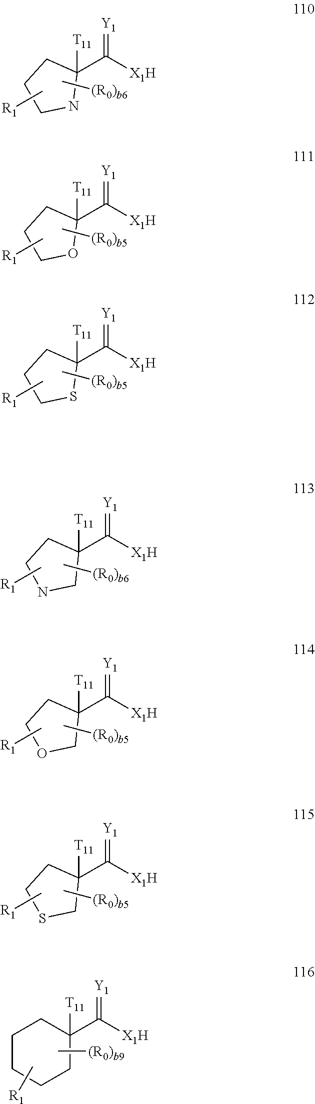

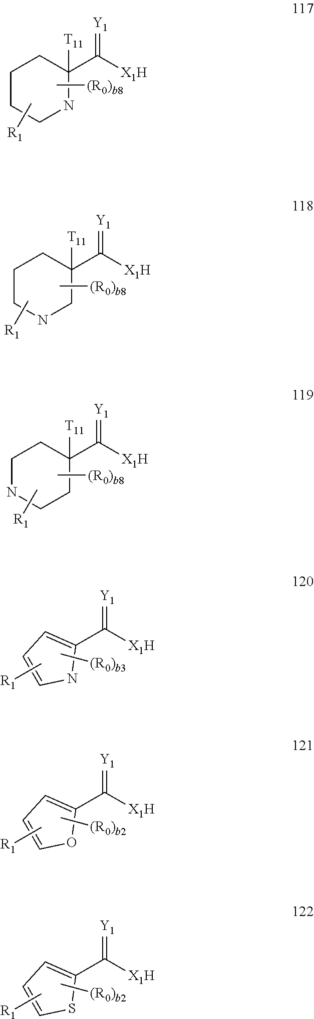

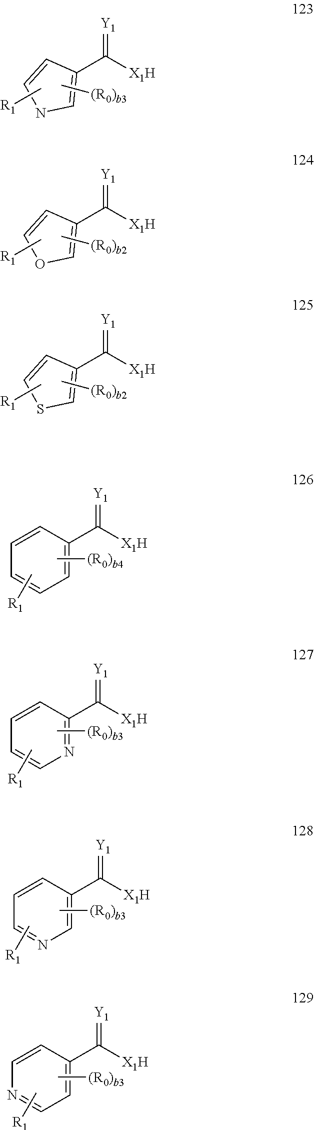

In Formulae 110 to 129,
the description of each of X₁, Y₁, R₁, and R₀ is the same as the description of each of X₁, Y₁, R₁, and R₀ in Formula 1.
b9 may be an integer from 0 to 9,
b8 may be an integer from 0 to 8,
b6 may be an integer from 0 to 6,
b5 may be an integer from 0 to 5,
b4 may be an integer from 0 to 4,
b3 may be an integer from 0 to 3,
b2 may be an integer from 0 to 2, and
the description of T₁₁ is the same as the description of R₁₁ of Formula 1 in this specification, but T₁₁ is not a hydroxyl group or a thiol group.

For example, in Formulae 110 to 129,
T₁₁ may be:
hydrogen, *—F, or *—NH₂; or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with *—F, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), or any combination thereof.

The amount (weight) of the accelerator may be, based on 100 wt % of the etching composition, about 0.001 wt % to about 20 wt %, about 0.001 wt % to about 15 wt %, about 0.001 wt % to about 10 wt %, about 0.001 wt % to about 7 wt %, about 0.001 wt % to about 5 wt %, about 0.001 wt % to about 4 wt %, about 0.001 wt % to about 3 wt %, about 0.001 wt % to about 2 wt %, about 0.001 wt % to about 1 wt %, about 0.001 wt % to about 0.5 wt %, about 0.001 wt % to about 0.1 wt %, about 0.005 wt % to about 20 wt %, about 0.005 wt % to about 15 wt %, about 0.005 wt % to about 10 wt %, about 0.005 wt % to about 7 wt %, about 0.005 wt % to about 5 wt %, about 0.005 wt % to about 4 wt %, about 0.005 wt % to about 3 wt %, about 0.005 wt % to about 2 wt %, about 0.005 wt % to about 1 wt %, about 0.005 wt % to about 0.5 wt %, about 0.005 wt % to about 0.1 wt %, about 0.01 wt % to about 20 wt %, about 0.01 wt % to about 15 wt %, about 0.01 wt % to about 10 wt %, about 0.01 wt % to about 7 wt %, about 0.01 wt % to about 5 wt %, about 0.01 wt % to about 4 wt %, about 0.01 wt % to about 3 wt %, about 0.01 wt % to about 2 wt %, about 0.01 wt % to about 1 wt %, about 0.01 wt % to about 0.5 wt %, about 0.01 wt % to about 0.1 wt %, about 0.05 wt % to about 20 wt %, about 0.05 wt % to about 15 wt %, about 0.05 wt % to about 10 wt %, about 0.05 wt % to about 7 wt %, about 0.05 wt % to about 5 wt %, about 0.05 wt % to about 4 wt %, about 0.05 wt % to about 3 wt %, about 0.05 wt % to about 2 wt %, about 0.05 wt % to about 1 wt %, about 0.05 wt % to about 0.5 wt %, or about 0.05 wt % to about 0.1 wt %. When the amount of the accelerator satisfies the range described above, the stability of the etching composition may be obtained.

### Ammonium Salt

The ammonium salt may etch the metal-containing layer.

The ammonium salt may include at least one of compounds having a structure in which at least one of the hydrogen ions (H⁺) of a hydroxyl group (*—OH) or a thiol group (*—SH) included in the accelerator is substituted with an ammonium cation (NH₄⁺). Accordingly, the etch rate and pH of the metal-containing layer of the etching composition may be more effectively controlled.

In addition, since the ammonium salt includes at least one of compounds having a structure in which at least one of the hydrogen ions (H⁺) of a hydroxyl group (*—OH) or a thiol group (*—SH) included in the accelerator is substituted with an ammonium cation (NH₄⁺), the etch rate ratio may not be substantially changed even when the etching composition is used after being stored at a high temperature (for example, about 70° C.) (for example, stored for 24 hours). As such, the etching composition can have excellent high-temperature stability, and thus, the process efficiency of a semiconductor device manufacturing method using an etching and/or CMP process using the etching composition can be improved.

According to an embodiment, the ammonium salt may include at least one of compounds represented by Formula 2:

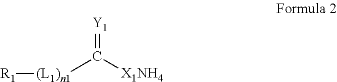

wherein, in Formula 2,
X₁ and Y₁ may each independently be O or S,
L₁ may be a single bond, a cyclic group having 2 to 10 carbon atoms unsubstituted or substituted with at least one R₀, *—C(R₁₁)(R₁₂)—**′, *—C(═O)—**′, *—C(═S)—**′, *—N(R₁₁)—**′, *—O—**′ or *—S—**′,
n1 may be an integer from 1 to 50,
when n1 is 2 or more, two or more of L₁ may be the same or different from each other,
R₁, R₁₁, R₁₂, and R₀ may each independently be:
hydrogen, deuterium, *—F, *—Cl, *—Br, *—I, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), *—NH—C(═S)—(NH₂), *—ONH₄, *˜SNH₄, *—C(═O)—ONH₄, *—C(═S)—ONH₄, *—C(═O)˜SNH₄, or *—C(═S)˜SNH₄; or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with deuterium, *—F, *—Cl, *—Br, *—I, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), *—NH—C(═S)—(NH₂), *—ONH₄, *˜SNH₄, *—C(═O)—ONH₄, *—C(═S)—ONH₄, *—C(═O)˜SNH₄, *—C(═S)˜SNH₄, or any combination thereof,
i) in the case where a second carbon directly bonded to a first carbon to which a hydroxyl group is bonded exists in Formula 2, a hydroxyl group (*—OH) and a thiol group (*—SH) are not bonded to the second carbon, and
ii) in the case where a fourth carbon directly bonded to a third carbon to which a thiol group is bonded exists in Formula 2, a hydroxyl group (*—OH) and a thiol group (*—SH) are not bonded to the fourth carbon.

For descriptions of L₁ and n1 in Formula 2, refer to the descriptions of L₁ and n1 in Formula 1, respectively.

According to an embodiment, the compound represented by Formula 2 may include one of compounds represented by Formulae 21, 22, 23, 23(1), 24, 24(1), 25, 26, 26(1), 26(2), 27, 27(1), 28, 29, 29(1), 29(2), 29(3) and 29(4), or any combination thereof:

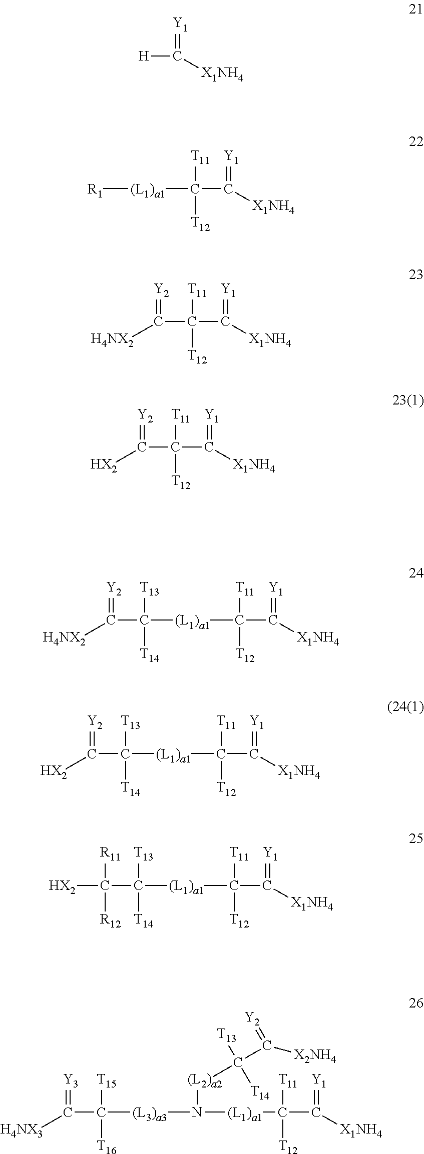

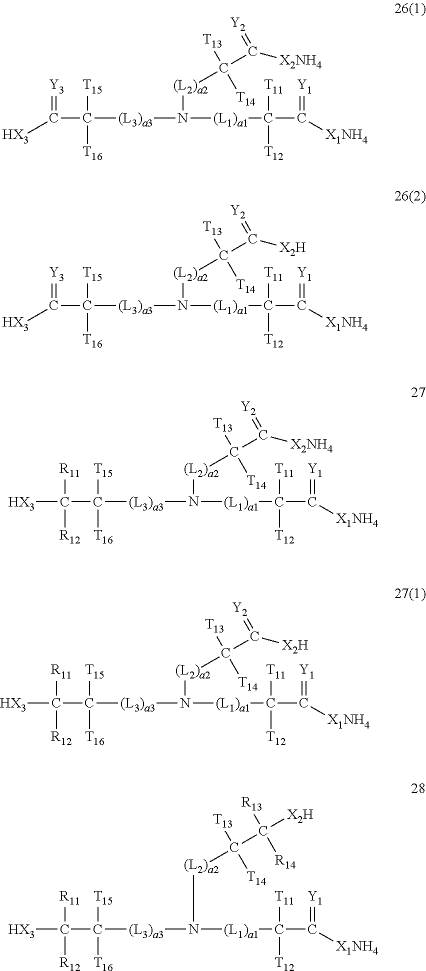

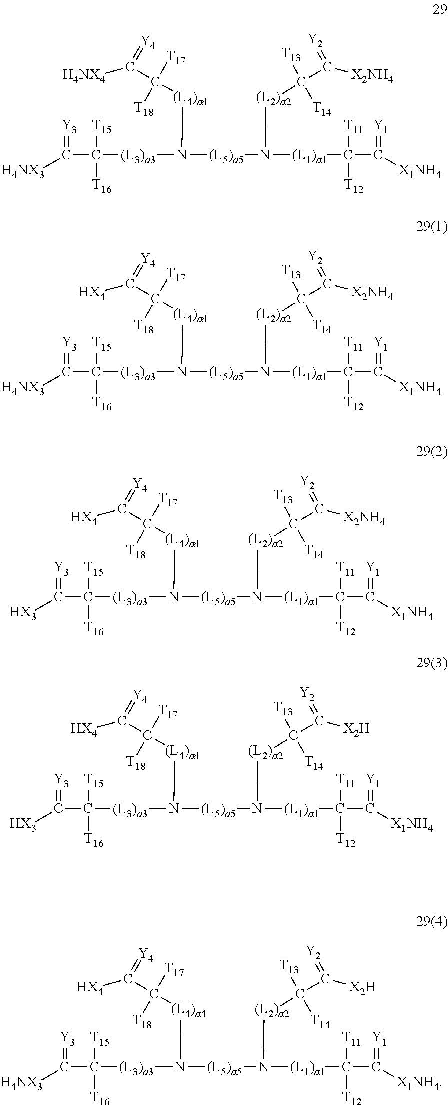

In Formulae 21, 22, 23, 23(1), 24, 24(1), 25, 26, 26(1), 26(2), 27, 27(1), 28, 29, 29(1), 29(2), 29(3), and 29(4),
the description of each of X₁, Y₁, L₁, R₁, R₁₁ and R₁₂ is the same as the description of each of X₁, Y₁, L₁, R₁, R₁₁, and R₁₂ in Formula 2 of this specification,
X₂, Y₂, X₃, Y₃, X₄, and Y₄ may each independently be O or S,
the description of each of L₂ to L₅ is the same as the description of L₁ of Formula 2 in this specification,
a1 to a5 may each independently be an integer from 1 to 15,
the description of each of R₁₃ and R₁₄ is the same as the description of R₁₁ in Formula 2 in this specification, and
the description of each of T₁₁ to T₁₈ is the same as the description of R₁₁ of Formula 2 in this specification, but each of T₁₁ to T₁₈ is not a hydroxyl group or a thiol group.

For example, in Formulae 21, 22, 23, 23(1), 24, 24(1), 25, 26, 26(1), 26(2), 27, 27(1), 28, 29, 29(1), 29(2), 29(3), and 29(4),
L₁ to L₅ may each independently be a single bond, *—C(R₁₁)(R₁₂)—**′, *—C(═O)—**′, *—C(═S)—**′, *—N(R₁₁)—**′, *—O—**′, or *—S—**′.

T₁₁ to T₁₈ may each independently be:
hydrogen, *—F, or *—NH₂; or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with *—F, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—ONH₄, *˜SNH₄, *—C(═O)—ONH₄, *—C(═S)—ONH₄, *—C(═O)—SNH₄, *—C(═S)˜SNH₄, or any combination thereof.

In some embodiments, the compound represented by Formula 2 may include one of compounds represented by Formulae 210 to 229, or any combination thereof:

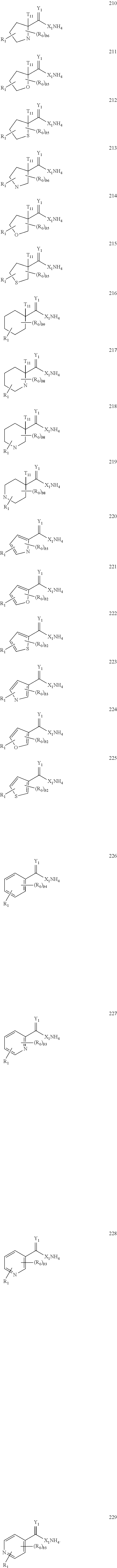

In Formulae 210 to 229,
the description of each of X₁, Y₁, R₁, and R₀ is the same as the description of each of X₁, Y₁, R₁, and R₀ in Formula 2,
b9 may be an integer from 0 to 9,
b8 may be an integer from 0 to 8,
b6 may be an integer from 0 to 6,
b5 may be an integer from 0 to 5,
b4 may be an integer from 0 to 4,
b3 may be an integer from 0 to 3,
b2 may be an integer from 0 to 2, and
the description of T₁₁ is the same as the description of R₁₁ of Formula 2 in this specification, but T₁₁ is not a hydroxyl group or a thiol group.

For example, in Formulae 210 to 229,
T₁₁ may be:
hydrogen, *—F, or *—NH₂; or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with *—F, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—ONH₄, *˜SNH₄, *—C(═O)—ONH₄, *—C(═S)—ONH₄, *—C(═O)—SNH₄, *—C(═S)˜SNH₄, or any combination thereof.

The amount (weight) of the ammonium salt may be, based on 100 wt % of the etching composition, about 0.5 wt % to about 20 wt %, about 0.5 wt % to about 10 wt %, about 1 wt % to about 20 wt %, about 0.5 wt % to about 10 wt %, about 1 wt % to about 7 wt %, or about 1 wt % to about 5 wt %.

In some embodiments, the ammonium salt may include different two or more of compounds having a structure in which at least one of the hydrogen ions (H⁺) of a hydroxyl group (*—OH) or a thiol group (*—SH) included in the accelerator is substituted with an ammonium cation (NH₄⁺). For example, the combination 1_{com1} in Table 1 below may be referred to.

In some embodiments, the ammonium salt may further include NH₄OH, tetramethylammonium hydroxide, etc., in addition to compounds having a structure in which at least one of the hydrogen ions (H⁺) of a hydroxyl group (*—OH) or a thiol group (*—SH) included in the accelerator included in the etching composition is substituted with an ammonium cation (NH₄⁺).

### Specific Examples of Accelerators and Ammonium Salts

The accelerator may include, for example, one of Compounds A1 to A29:

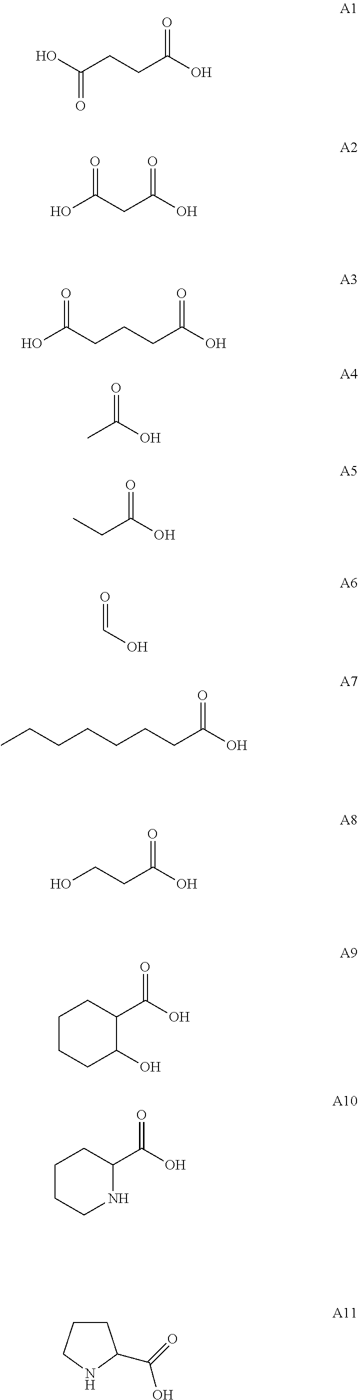

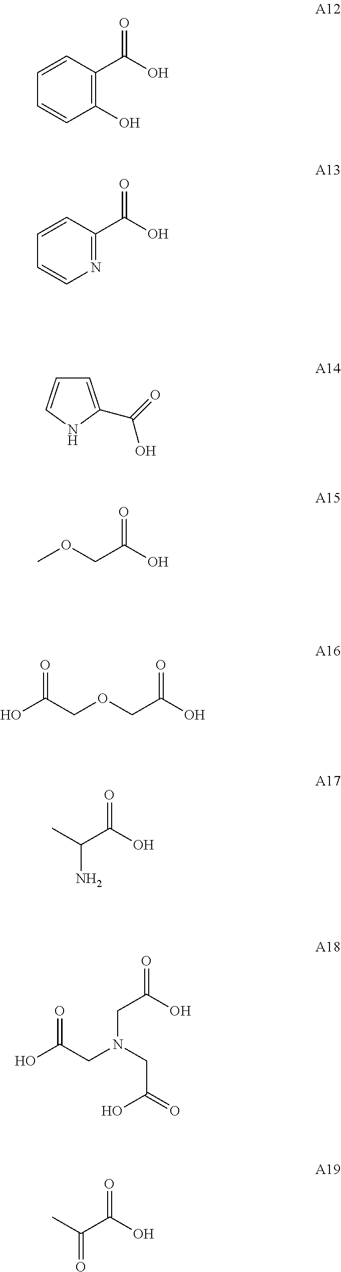

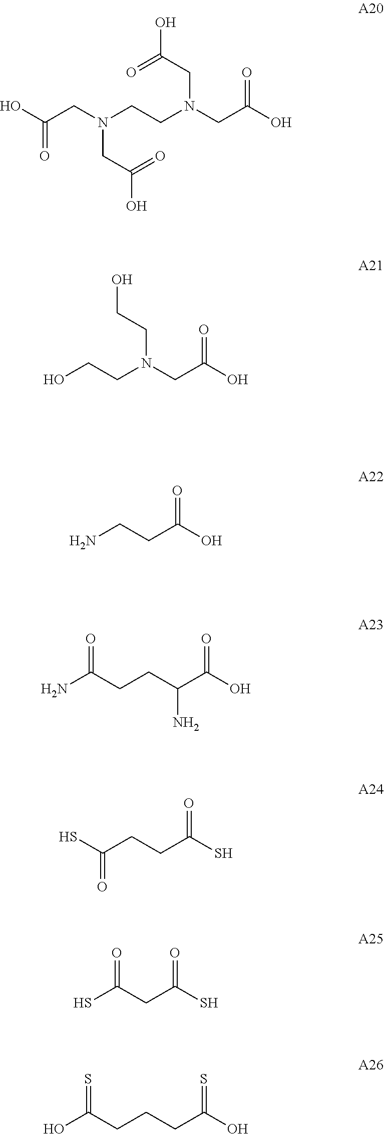

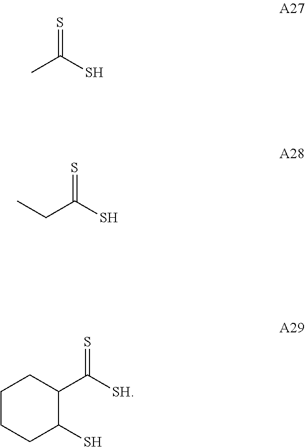

Compounds A1 to A29 satisfy the condition “i) in the case where a second carbon directly bonded to a first carbon to which a hydroxyl group is bonded exists in Formula 1, a hydroxyl group (*—OH) and a thiol group (*—SH) are not bonded to the second carbon, and the condition ii) in the case where a fourth carbon directly bonded to a third carbon to which a thiol group is bonded exists in Formula 1, a hydroxyl group (*—OH) and a thiol group (*—SH) are not bonded to the fourth carbon. For understanding, the first carbon, the second carbon, the third carbon, and the fourth carbon of Compounds A1 to A29 are indicated with “1,” “2,” “3,” and “4,” respectively, as shown below:

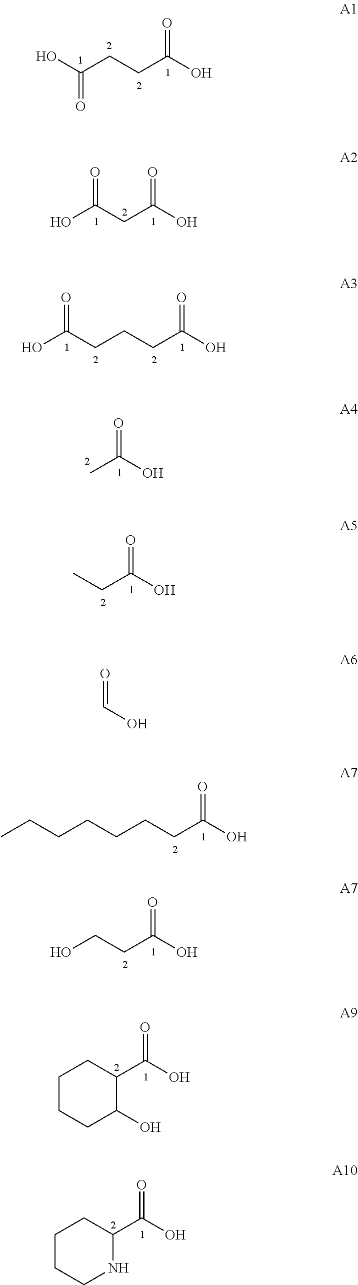

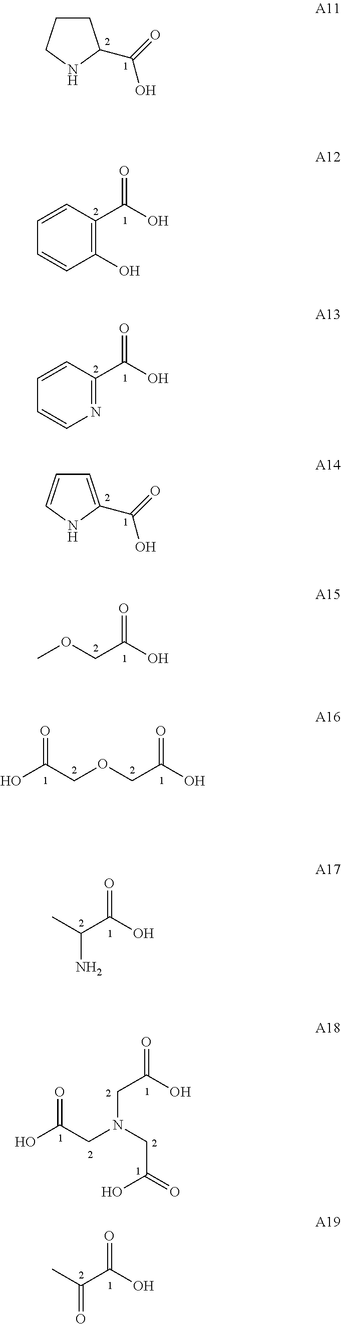

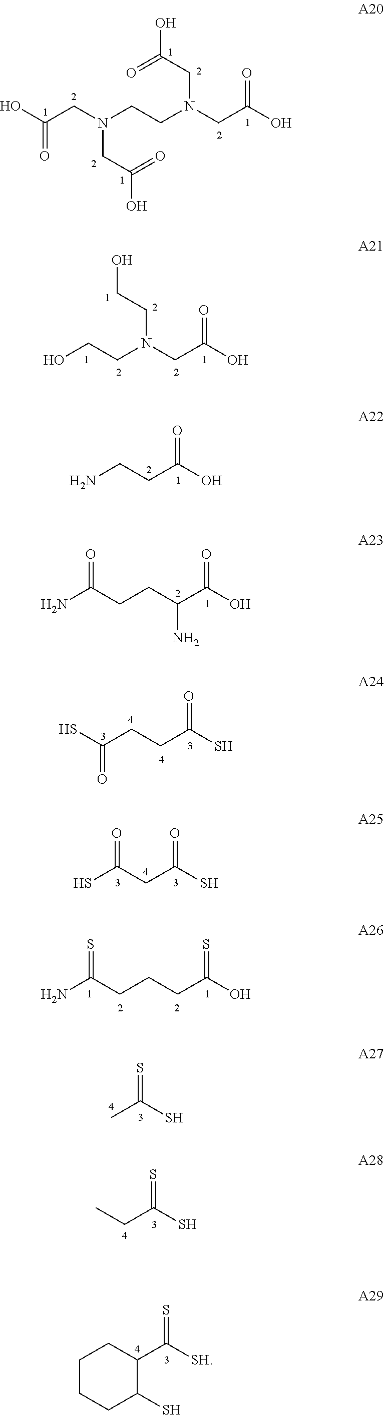

In addition, the ammonium salt may include, for example, at least one of Compounds S1 to S29, S1(1), S2(1), S3(1), S16(1), S18(1), S18(2), S20(1), S20(2), S20 (3), S20 (4), S24(1), S25(1), and S26 (1):

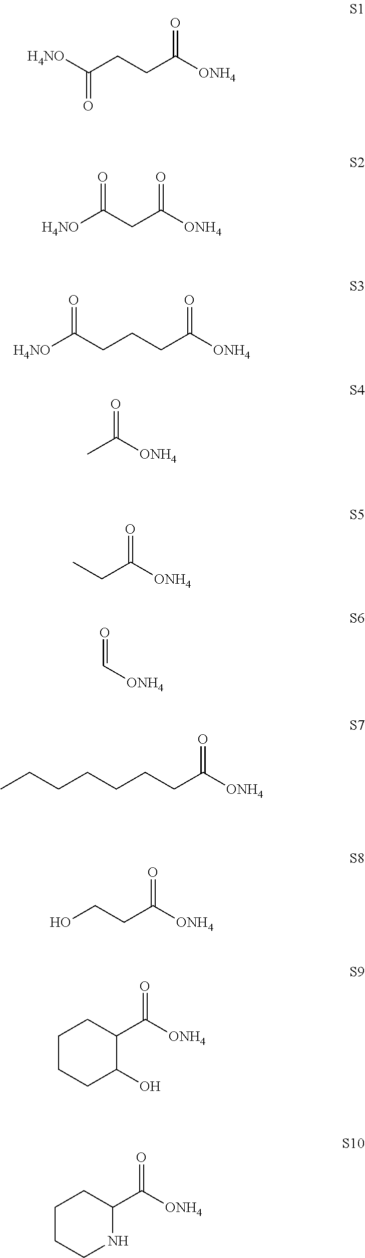

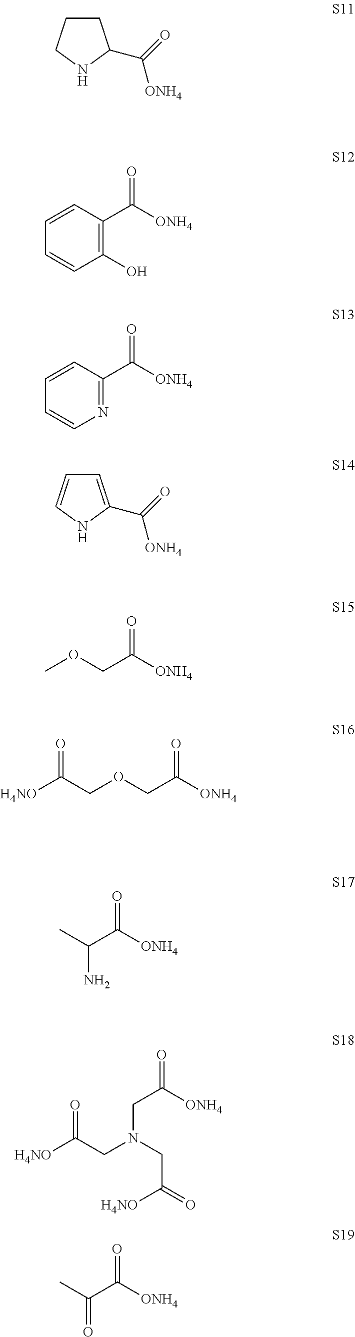

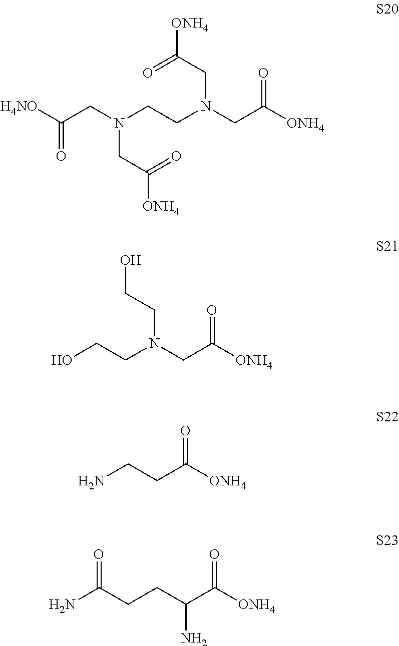

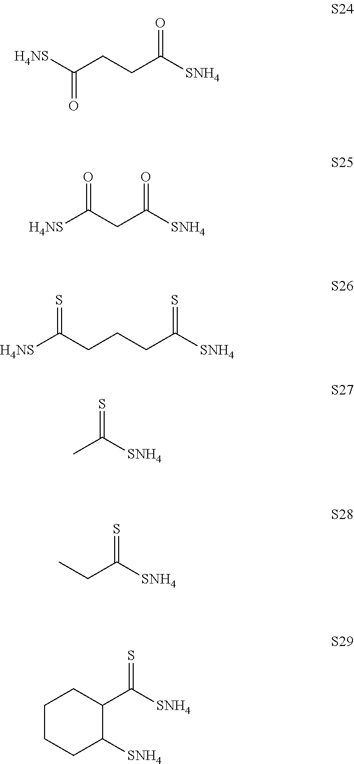

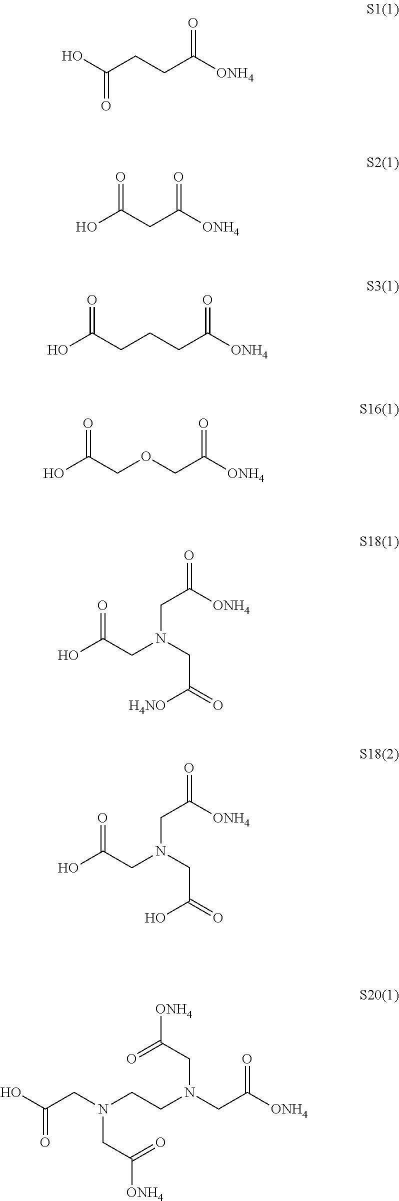

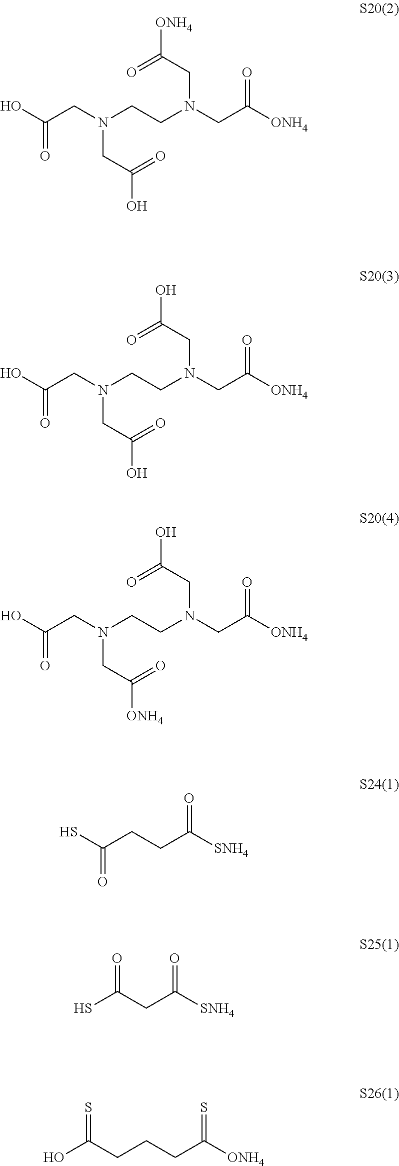

The ammonium salt contained in the etching composition includes a compound having structure in which at least one of the hydrogen ions (H⁺) of the hydroxyl group (*—OH) or thiol group (*—SH) contained in the accelerator is substituted with an ammonium cation (NH₄⁺). Accordingly, the combination of an accelerator and an ammonium salt included in the etching composition may be one of the combinations listed in Table 1 below:

TABLE 1

| Combination | | |
|---|---|---|
| No. | Accelerator | Ammonium salt |
| 1 | A1 | S1 |
| 2 | A2 | S2 |
| 3 | A3 | S3 |
| 4 | A4 | S4 |
| 5 | A5 | S5 |
| 6 | A6 | S6 |
| 7 | A7 | S7 |
| 8 | A8 | S8 |
| 9 | A9 | S9 |
| 10 | A10 | S10 |
| 11 | A11 | S11 |
| 12 | A12 | S12 |
| 13 | A13 | S13 |
| 14 | A14 | S14 |
| 15 | A15 | S15 |
| 16 | A16 | S16 |
| 17 | A17 | S17 |
| 18 | A18 | S18 |
| 19 | A19 | S19 |
| 20 | A20 | S20 |
| 21 | A21 | S21 |
| 22 | A22 | S22 |
| 23 | A23 | S23 |
| 24 | A24 | S24 |
| 25 | A25 | S25 |
| 26 | A26 | S26 |
| 27 | A27 | S27 |
| 28 | A28 | S28 |
| 29 | A29 | S29 |
| 1(1) | A1 | S1(1) |
| 1_{com1} | A1 | S1 and S1(1) |
| 2(1) | A2 | S2(1) |
| 2_{com1} | A2 | S2 and S2(1) |
| 3(1) | A3 | S3(1) |
| 3_{com1} | A3 | S3 and S3(1) |
| 16(1) | A16 | S16(1) |
| 16_{com1} | A16 | S16 and S16(1) |
| 18(1) | A18 | S18(1) |
| 18(2) | A18 | S18(2) |
| 18_{com1} | A16 | S18 and S18(1) |
| 18_{com2} | A16 | S18 and S18(2) |
| 18_{com3} | A16 | S18, S18(1), and S18(2) |
| 20(1) | A20 | S20(1) |
| 20(2) | A20 | S20(2) |
| 20(3) | A20 | S20(3) |
| 20(4) | A20 | S20(4) |
| 20_{com1} | A20 | S20 and S20(1) |
| 20_{com2} | A20 | S20 and S20(2) |
| 20_{com3} | A20 | S20 and S20(3) |
| 20_{com4} | A20 | S20 and S20(4) |
| 20_{com5} | A20 | S20(1) and S20(2) |
| 20_{com6} | A20 | S20(1) and S20(3) |
| 20_{com7} | A20 | S20(1) and S20(4) |
| 20_{com8} | A20 | S20(2) and S20(3) |
| 20_{com9} | A20 | S20(2) and S20(4) |
| 20_{com10} | A20 | S20(3) and S20(4) |
| 20_{com11} | A20 | S20, S20(1) and S20(2) |
| 20_{com12} | A20 | S20, S20(1) and S20(3) |
| 20_{com13} | A20 | S20, S20(1) and S20(4) |
| 20_{com14} | A20 | S20, S20(2) and S20(3) |
| 20_{com15} | A20 | S20, S20(2) and S20(4) |
| 20_{com16} | A20 | S20, S20(3) and S20(4) |
| 20_{com17} | A20 | S20(1), S20(2) and S20(3) |
| 20_{com18} | A20 | S20(1), S20(2), and S20(4) |
| 20_{com19} | A20 | S20(1), S20(3), and S20(4) |
| 20_{com20} | A20 | S20(2), S20(3), and S20(4) |
| 20_{com21} | A20 | S20, S20(1), S20(2), and S20(3) |
| 20_{com22} | A20 | S20, S20(1), S20(2), and S20(4) |
| 20_{com23} | A20 | S20, S20(1), S20(3), and S20(4) |
| 20_{com24} | A20 | S20, S20(2), S20(3), and S20(4) |
| 20_{com25} | A20 | S20(1), S20(2), S20(3), and S20(4) |
| 20_{com26} | A20 | S20, S20(1), S20(2), S20(3), and S20(4) |
| 24(1) | A24 | S24(1) |
| 24_{com1} | A24 | S24 and S24(1) |
| 25(1) | A25 | S25(1) |
| 25_{com1} | A25 | S25 and S25(1) |
| 26(1) | A26 | S26(1) |
| 26_{com1} | A26 | S26 and S26(1) |

The etching composition may have a pH of about 1 to about 7, for example, about 2 to about 6. When the etching composition has these ranges of pH, chelating between the accelerator and ammonium salt and the metal, as described later, can be more effectively achieved.

According to an embodiment, the etching composition may be used in a metal-containing layer etching process and/or a CMP process. The metal-containing layer is as described in the present specification.

In some embodiments, the etching composition may be used as an etching by-product remover, a post-etch process by-product remover, an ashing process by-product remover, a cleaning composition, a photoresist (PR) remover, an etching composition for a packaging process, a cleaner for a packaging process, a wafer adhesive remover, an etchant, a post-etch residue stripper, an ash residue cleaner, a photoresist (PR) residue stripper, a CMP cleaner, or a post-CMP cleaner.

Metal-containing layer etching method and semiconductor device manufacturing method

A metal-containing layer can be more effectively etched using the etching composition described above.

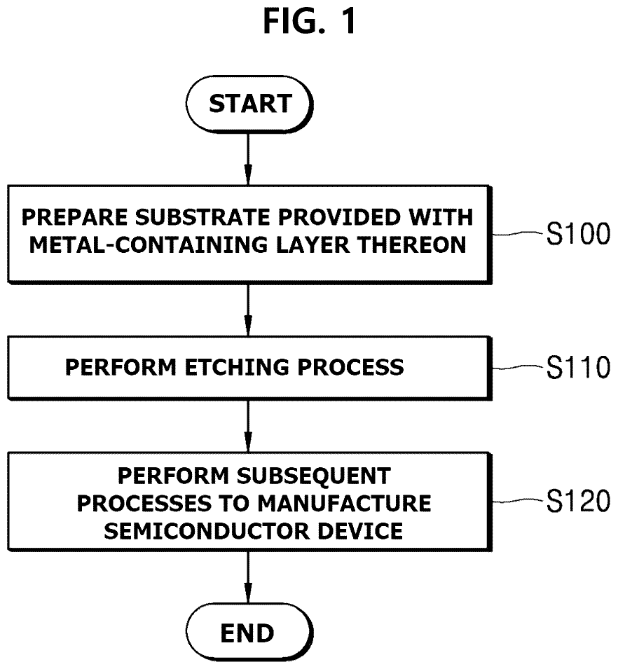

Referring to FIG. 1, an embodiment of the method of etching a metal-containing layer includes: preparing a substrate provided with a metal-containing layer thereon (S100); and performing an etching process on the metal-containing layer using the etching composition as described in this specification to remove at least a portion of the metal-containing layer (S110).

The metal-containing layer is as described in the present specification.

For example, the metal-containing layer may include indium (In), titanium (Ti), aluminum (Al), tungsten (W), lanthanum (La), scandium (Sc), gallium (Ga), zinc (Zn), hafnium (Hf), molybdenum (Mo), or any combination thereof.

In some embodiments, the metal-containing layer may include metal, metal nitride, metal oxide, metal oxynitride, or any combination thereof.

Due to the inclusion of a combination of the accelerator and the ammonium salt as described above, the etching composition may have a more effectively controlled etching selectivity for the metal-containing layer, thereby increasing the efficiency, accuracy, and productivity of the etching process. Therefore, a semiconductor device with excellent performance can be manufactured by using a metal-containing layer etching process using the etching composition described above.

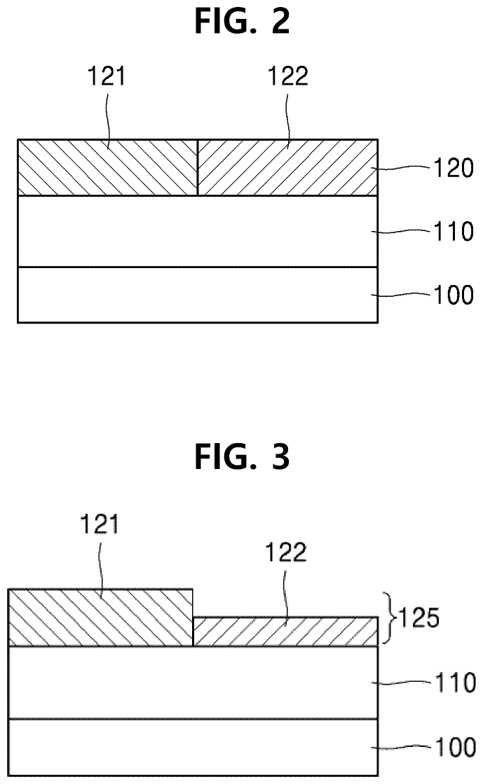

FIGS. 2 and 3 are diagrams briefly explaining an embodiment of a method of etching a metal-containing layer 120.

Referring to FIG. 2, a substrate 100 provided with the metal-containing layer 120 thereon is provided. The interlayer 110 may be disposed between the substrate 100 and the metal-containing layer 120. Although not shown in FIG. 2, circuit elements (for example, transistor gates, metal lines, impurity regions, and/or semiconductor layers) may be disposed, for example, inside the substrate 100, on the substrate 100, and/or between the substrate 100 and the interlayer 110. According to an embodiment, the metal-containing layer 120 may be disposed directly on the substrate 100 and the interlayer 110 may be omitted.

The metal-containing layer 120 may include a first region 121 and a second region 122. A second etch rate at which the etching composition etches the second region 122 may be greater than a first etch rate at which the etching composition etches the first region 121.

Referring to FIG. 3, the etching composition is used to etch the metal-containing layer 120 to etch at least a portion of the first region 121 and at least a portion of the second region 122 to form a pattern of the metal-containing layer 125. The etching process may be performed by contacting each of at least a portion of the first region 121 and at least a portion of the second region 122 with the etching composition.

The etching composition may etch at least a portion of the first region 121 and at least a portion of the second region 122. In FIG. 3, the pattern of the metal-containing layer 125 formed after etching may include at least a portion of the second region 122, but if necessary, the embodiment may be variously modified, for example, the etching process may be performed to completely remove the second region 122 of the pattern of the metal-containing layer 125.

In some embodiments, the first region 121 may include metal oxide (for example, aluminum oxide), silicon oxide, or any combination thereof.

In some embodiments, the second region 122 may include metal nitride (for example, titanium nitride).

In some embodiments, the second region 122 may include i) titanium nitride (TiN), ii) titanium nitride further including indium, aluminum, lanthanum, scandium, gallium, zinc, hafnium, or any combination thereof (for example, TiAlN), or iii) any combination thereof.

In some embodiments, the first region 121 and the second region 122 may each include i) titanium nitride (TiN), ii) titanium nitride further including indium, aluminum, lanthanum, scandium, gallium, zinc, hafnium, or any combination thereof (for example, TiAlN), or iii) any combination thereof.

In some embodiments, the first region 121 may include aluminum, and the second region 122 may not include aluminum.

In some embodiments, the first region 121 may include aluminum oxide, and the second region 122 may include i) titanium nitride (TiN), ii) titanium nitride further including indium, aluminum, lanthanum, scandium, gallium, zinc, hafnium, or any combination thereof (for example, TiAlN), or iii) any combination thereof.

In some embodiments, the first region 121 may include aluminum oxide, and the second region 122 may include titanium nitride (TiN), titanium nitride further including aluminum (TiAlN), or any combination thereof.

In some embodiments, the first region 121 may include an aluminum oxide layer, and the second region 122 may include a titanium nitride layer (TiN layer), a titanium nitride layer further including aluminum (for example, a titanium aluminum nitride layer, or TiAlN layer), or any combination thereof.

In some embodiments, the first region 121 may be an aluminum oxide layer, and the second region 122 may be a titanium nitride layer (TiN layer) or a titanium nitride layer further including aluminum (for example, a titanium aluminum nitride layer or a TiAlN layer).

In some embodiments, the first region 121 may include titanium nitride further including aluminum (for example, TiAlN), and the second region 122 may include titanium nitride (TiN).

In some embodiments, the first region 121 may include a titanium nitride layer further including aluminum (for example, a TiAlN layer), and the second region 122 may include titanium nitride layer (TiN layer).

In some embodiments, the first region 121 may be a titanium nitride layer further including aluminum (for example, TiAlN layer), and the second region 122 may be a titanium nitride layer (TiN layer).

In some embodiments, the etch rate ratio of the second region 122 to the first region 121 of the etching composition may be about 110 to about 700, about 150 to about 700, about 200 to about 700, about 255 to about 700, about 110 to about 600, about 150 to about 600, about 200 to about 600, about 255 to about 600, about 110 to about 500, about 150 to about 500, about 200 to about 500, about 255 to about 500, about 110 to about 440, about 150 to about 440, about 200 to about 440, or about 255 to about 440. The etch rate ratio of the second region 122 to the first region 121 may be obtained by dividing the second etch rate at which the etching composition etches the second region 122 by the first etch rate at which the etching composition etches the first region 121. When the etch rate ratio of the second region 122 to the first region 121 of the etching composition satisfies the range described above, the efficiency and productivity of the etching process can be improved.

In some embodiments, the first region 121 includes aluminum oxide, the second region 122 includes titanium nitride or titanium nitride further including aluminum, and the etch rate ratio of the second region 122 with respect to the first region 121 of the etching composition may be about 110 to about 700, about 150 to about 700, about 200 to about 700, about 255 to about 700, about 110 to about 600, about 150 to about 600, about 200 to about 600, about 255 to about 600, about 110 to about 500, about 150 to about 500, about 200 to about 500, about 255 to about 500, about 110 to about 440, about 150 to about 440, about 200 to about 440, or about 255 to about 440.

Referring to FIG. 1, a method of manufacturing semiconductor device according to an embodiment includes preparing a substrate provided with a metal-containing layer thereon (S100); performing an etching process on the metal-containing layer using the etching composition to remove at least a portion of the metal-containing layer (S110); and performing a subsequent process to manufacture a semiconductor device (S120).

Hereinafter, one or more example embodiments will be described in further detail with reference to the following examples and comparative examples. These examples and comparative examples are not intended to limit the scope of inventive concepts. Examples 1 to 6 and Comparative Examples A to D

The materials shown in Tables 2 and 3 below were mixed in the amounts shown in Tables 2 and 3 to prepare etching compositions for Examples 1 to 6 and Comparative Examples A to D. Hydrogen peroxide was used as an oxidizing agent for each etching composition, and the remainder corresponds to water (deionized water).

### Evaluation Example 1 (Etching Rate Ratio Evaluation)

The etching composition of Example 1 was placed in two beakers and heated to 70° C., and then a 1 cm×1 cm titanium aluminum nitride layer (TiAlN layer) specimen and a 1 cm×1 cm aluminum oxide layer specimen were immersed in respective beakers for 5 minutes. Then, the thickness of each of the titanium aluminum nitride layer and the aluminum oxide layer was measured using an ellipsometer (M-2000, JAWoolam), a four-point resistance meter, and X-ray fluorescence (XRF) spectrometer, so as to evaluate each of the etch rate for the titanium aluminum nitride layer and the etch rate for the aluminum oxide layer (Å/min) of the etching composition of Example 1. Next, the etch rate for the titanium aluminum nitride layer was divided by the etch rate for the aluminum oxide layer to evaluate the R (TiAlN/AlO) of the etching composition of Example 1. Results thereof are summarized in Table 2.

This test was repeatedly carried out using each of the etching compositions of Example 2, Example 3, and Comparative Example A. Results thereof are summarized in Table 2.

TABLE 2

| | | | | | | TiAIN | | |
|---|---|---|---|---|---|---|---|---|
| | Oxidizing | | | | | layer | Aluminum | |
| | agent | Accelerator | | Ammonium salt | | etch | oxide | R |
| | Amount | | Amount | | Amount | rate | etch rate | (TIAIN/ |
| | (wt % ) | Material | (wt %) | Material | (wt %) | (Å/min) | (Å/min) | AIO) |
| Example 1 | 20 | A1 | 0.05 | S1 | 3 | 40 | 0.1 | 400 |
| (Combination 1) | | | | | | | | |
| Example 2 | 20 | A3 | 0.05 | S3 | 3 | 44 | 0.1 | 440 |
| (Combinationtion 3) | | | | | | | | |
| Example 3 | 20 | A19 | 0.05 | S19 | 3 | 51 | 0.2 | 255 |
| (Combinationtion 19) | | | | | | | | |
| Comparative | 20 | AR | 0.05 | SR | 3 | 84 | 0.8 | 105 |
| example A | | | | | | | | |

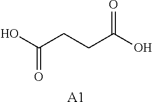

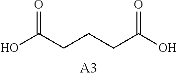

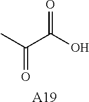

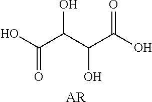

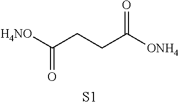

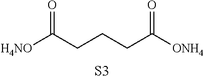

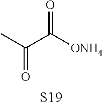

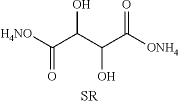

From Table 2, it can be seen that the etching compositions of Examples 1 to 3 have an excellent etch rate ratio compared to the etching composition of Comparative Example A.

### Evaluation Example 2 (High-Temperature Stability Evaluation)

R(TiAlN/AlO) of the etching composition of Example 4 was evaluated using the same method as Evaluation Example 1. This is referred to as “R_{0 hr}” of the etching composition of Example 4.

The etching composition of Example 4 was placed in two beakers and heated to 70° C., and then a 1 cm×1 cm titanium aluminum nitride layer (TiAlN layer) specimen and a 1 cm×1 cm aluminum oxide layer specimen were immersed in respective beakers for 24 hours. Then, the thickness of each of the titanium aluminum nitride layer and the aluminum oxide layer was measured using an ellipsometer (M-2000, JAWoolam), a four-point resistance meter, and XRF, so as to evaluate each of the etch rate for the titanium aluminum nitride layer and the etch rate for the aluminum oxide layer (Å/min) of the etching composition of Example 4. Then, the etch rate for the titanium aluminum nitride film was divided by the etch rate for the aluminum oxide film, to evaluate the R(TiAlN/AlO) of the etching composition of Example 4 stored at high temperature for 24 hours. This is referred to as “R₂₄ hr” of the etching composition of Example 4.

From this, “[(R_{0 hr}-R_{24 hr})/R_{0 hr}]×100”(%) of the etching composition 4 was calculated to evaluate the change rate (%) of the etch rate ratio before and after high temperature storage of the etching composition of Example 4. Results thereof are summarized in Table 3.

This test was repeatedly carried out using each of the etching compositions of Comparative Example B, Example 5, Comparative Example C, Example 6, and Comparative Example D. Results thereof are summarized in Table 3.

TABLE 3

| | Oxidizing | | | | | High temperature |
|---|---|---|---|---|---|---|
| | agent | Accelerator | | Ammonium salt | | stability |
| | amount | | amount | | amount | (etch rate ratio change |
| | (wt %) | material | (wt %) | material | (wt %) | rate, %) |
| Example 4 | 20 | A2 | 0.05 | S2 | 3 | 2.4% |
| (Combination 2) | | | | | | |
| Comparative | 20 | A2 | 0.05 | Ammonium | 3 | 4.3% |
| Example B | | | | acetate | | |
| Example 5 | 20 | A11 | 0.05 | S11 | 3 | 2.1% |
| (Combination 11) | | | | | | |
| Comparative | 20 | A11 | 0.05 | Ammonium | 3 | 3.9% |
| example C | | | | acetate | | |
| Example 6 | 20 | A13 | 0.05 | S13 | 3 | 3.5% |
| (Combination 13) | | | | | | |
| Comparative | 20 | A13 | 0.05 | Ammonium | 3 | 6.8% |
| example D | | | | acetate | | |

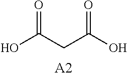

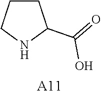

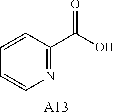

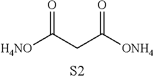

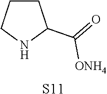

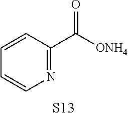

From Table 3, the etching compositions of Example 4, Example 5, and Example 6 each have a lower etch rate ratio change rate than each of the etching compositions of Comparative Example B, Comparative Example C, and Comparative Example D. Accordingly, it can be confirmed that the etching compositions of the present disclosure has excellent high temperature stability.

The etching composition has more effectively controlled etching selectivity and, at the same time, high-temperature stability, for the metal-containing layer that is the etching target layer. Accordingly, the efficiency, accuracy, and productivity of the etching process can be increased. Therefore, by using the etching composition, a more effective etching process and/or CMP process can be performed on the to-be-etched layer. Therefore, a semiconductor device manufactured using a metal-containing layer etching process using the etching composition can have excellent performance.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An etching composition comprising:
an oxidizing agent;
an accelerator;
an ammonium salt; and
an aqueous solvent, wherein
the accelerator includes one or more compounds represented by Formula 1 below, and
the ammonium salt includes at least one compound having a structure in which at least one of hydrogen ions (H⁺) of a hydroxyl group (*—OH) or a thiol group (*—SH) included in the accelerator is substituted with an ammonium cation (NH₄⁺); 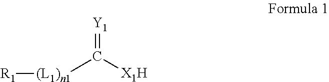
wherein, in Formula 1,
X₁ and Y₁ are each independently O or S,
L₁ is a single bond, a cyclic group having 2 to 10 carbon atoms unsubstituted or substituted with at least one R₀, *—C(R₁₁)(R₁₂)—**′, *—C(═O)—**′, *—C(═S)—**′, *—N(R₁₁)—**′, *—O—**′, or *—S—**′,
n1 is an integer from 1 to 50,
when n1 is 2 or more, two or more of L₁ are the same or different from each other,
R₁, R₁₁, R₁₂ and R₀ are each independently:
hydrogen, deuterium, *—F, *—Cl, *—Br, *—I, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), or *—NH—C(═S)—(NH₂); or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with deuterium, *—F, *—Cl, *—Br, *—I, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), *—NH—C(═S)—(NH₂), or any combination thereof,
when a second carbon directly bonded to a first carbon to which a hydroxyl group is bonded exists in Formula 1, a hydroxyl group (*—OH) and a thiol group (*—SH) are not bonded to the second carbon, and
when a fourth carbon directly bonded to a third carbon to which a thiol group is bonded exists in Formula 1, a hydroxyl group (*—OH) and a thiol group (*—SH) are not bonded to the fourth carbon.

2. The etching composition of claim 1, wherein
the oxidizing agent comprises hydrogen peroxide.

3. The etching composition of claim 1, wherein
an amount of the oxidizing agent is 1 wt % to 50 wt %, based on 100 wt % of the etching composition.

4. The etching composition of claim 1, wherein
in Formula 1, L₁ is a cyclic group having 2 to 10 carbon atoms unsubstituted or substituted with at least one R₀, and
n1 is 1.

5. The etching composition of claim 1, wherein
L₁ in Formula 1 is a cyclopentane group, a cyclohexane group, a cycloheptane group, a cyclooctane group, a cyclopentene group, a cyclohexene group, a cycloheptene group, a cyclooctene group, a cyclopentadiene group, a benzene group, a cycloheptadiene group, a cyclooctadiene group, a pyrrolidine group, a tetrahydrofuran group, a tetrahydrothiophene group, a piperidine group, a tetrahydro-2H-pyran group, a tetrahydro-2H-thiopyran group, an azepane group, an oxepane group, a thiepane group, a 2,3-dihydro-1H-pyrrole group, a 2,3-dihydrofuran group, a 2,3-dihydrothiophene group, a 2,5-dihydro-1H-pyrrole group, a 2,5-dihydrofuran group, a 2,5-dihydrothiophene group, a pyrrole group, a furan group, a thiophene group, a pyridine group, a pyrimidine group, a pyrazine group, a pyridazine group, or a triazine group, each unsubstituted or substituted with at least one R₀.

6. The etching composition of claim 1, wherein
in Formula 1, L₁ is a single bond, *—C(R₁₁)(R₁₂)—**′, *—C(═O)—**′, *—C(═S)—**′, *—N(R₁₁)—*′, *—O—**′, or *—S—**′, and
n1 is an integer from 1 to 20.

7. The etching composition of claim 1, wherein R₁, R₁₁, R₁₂, and R₀ are each independently:
hydrogen, *—F, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), or *—C(═S)—(NH₂); or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with *—F, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), or any combination thereof.

8. The etching composition of claim 1, wherein
the compound represented by Formula 1 includes one of compounds represented by Formulae 11 to 19, or any combination thereof: 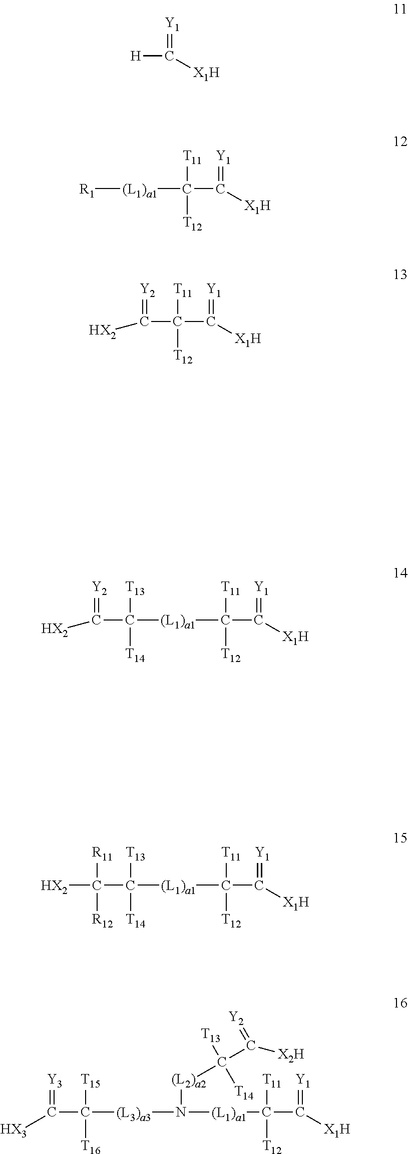 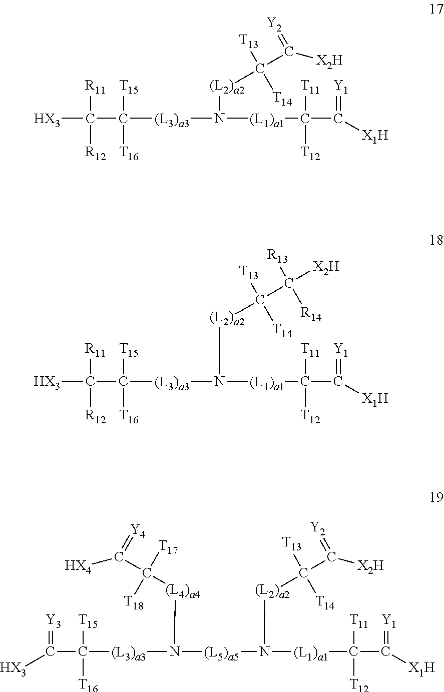
wherein, in Formulae 11 to 19,
X₁, X₂, Y₁, Y₂, X₃, Y₃, X₄, and Y₄ are each independently O or S,
L₁ to L₅ each independently are a single bond, a cyclic group having 2 to 10 carbon atoms unsubstituted or substituted with at least one R₀, *—C(R₁₁)(R₁₂)—**′, *—C(═O)—**′, *—C(═S)—**′, *—N(R₁₁)—**′, *—O—**′, or *—S—**′,
a1 to a5 are each independently an integer from 1 to 15,
R₁, R₁₁ R₁₂, R₁₃, R₁₄ and R₀ are each independently:
hydrogen, deuterium, *—F, *—Cl, *—Br, *—I, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), or *—NH—C(═S)—(NH₂); or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with deuterium, *—F, *—Cl, *—Br, *—I, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), *—NH—C(═S)—(NH₂), or any combination thereof, and
T₁₁ to T₁₈ are each independently:
hydrogen, deuterium, *—F, *—Cl, *—Br, *—I, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), or *—NH—C(═S)—(NH₂); or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with deuterium, *—F, *—Cl, *—Br, *—I, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), *—NH—C(═S)—(NH₂), or any combination thereof.

9. The etching composition of claim 8, wherein
in Formulae 11 to 19,
L₁ to L₅ are each independently a single bond, *—C(R₁₁)(R₁₂)—*, *—C(═O)—*, *—C(═S)—*, *—N(R₁₁)—*, *—O—*, or *—S—*, and
T₁₁ to T₁₈ are each independently:
hydrogen, *—F, or *—NH₂; or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with *—F, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), or any combination thereof.

10. The etching composition of claim 1, wherein
the compound represented by Formula 1 includes one of compounds represented by Formulae 110 to 129, or any combination thereof: 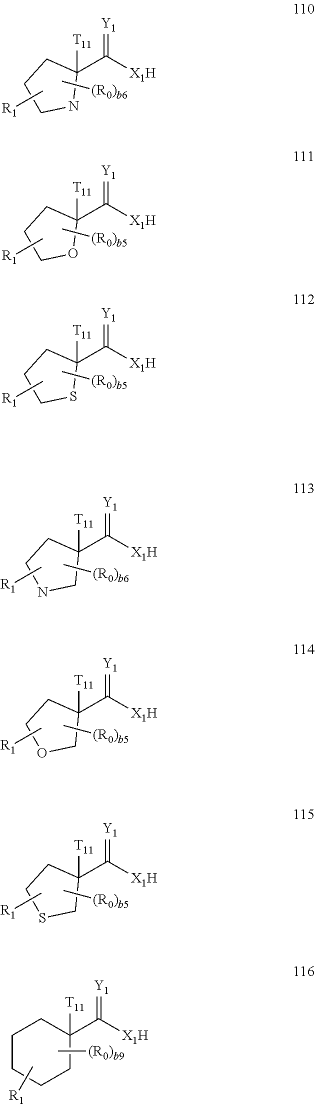 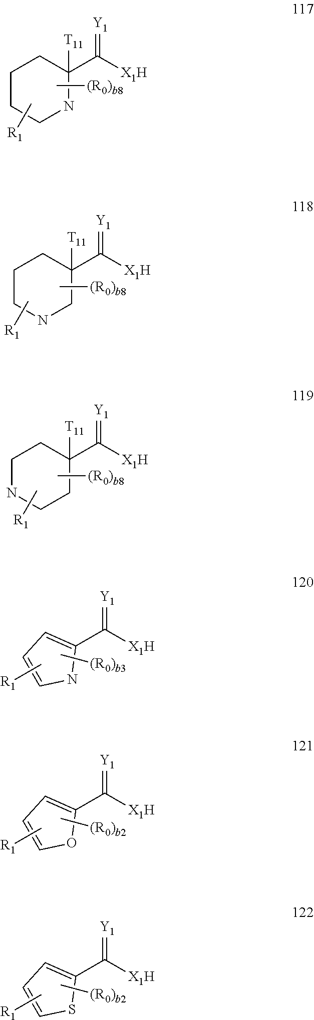 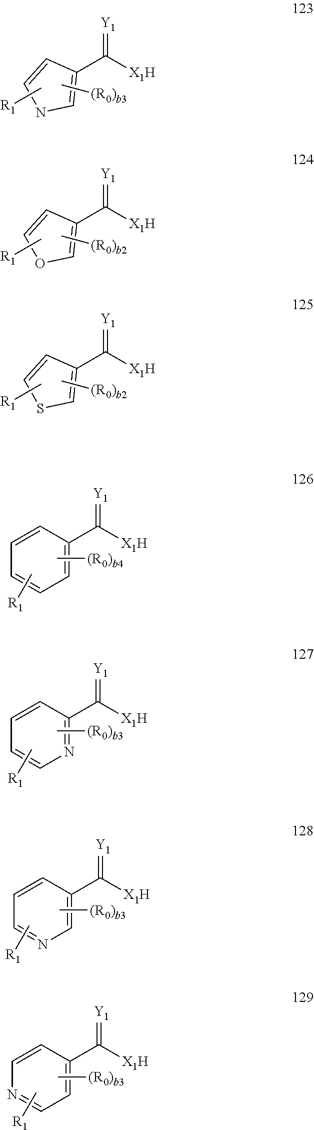
wherein, in Formulae 110 to 129,
X₁ and Y₁ are each independently O or S,
R₁ and R₀ are each independently:
hydrogen, deuterium, *—F, *—Cl, *—Br, *—I, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), or *—NH—C(═S)—(NH₂); or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with deuterium, *—F, *—Cl, *—Br, *—I, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), *—NH—C(═S)—(NH₂), or any combination thereof,
b9 is an integer from 0 to 9,
b8 is an integer from 0 to 8,
b6 is an integer from 0 to 6,
b5 is an integer from 0 to 5,
b4 is an integer from 0 to 4,
b3 is an integer from 0 to 3,
b2 is an integer from 0 to 2, and
T₁₁ is one of:
hydrogen, deuterium, *—F, *—Cl, *—Br, *—I, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), or *—NH—C(═S)—(NH₂); or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with deuterium, *—F, *—Cl, *—Br, *—I, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), *—NH—C(═S)—(NH₂), or any combination thereof.

11. The etching composition of claim 10, wherein
in Formulae 110 to 129,
T₁₁ is:
hydrogen, *—F, or *—NH₂; or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with *—F, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), or any combination thereof.

12. The etching composition of claim 1, wherein
an amount of the accelerator is 0.001 wt % to 20 wt %, based on 100 wt % of the etching composition.

13. The etching composition of claim 1, wherein
the ammonium salt includes one or more compounds represented by Formula 2: 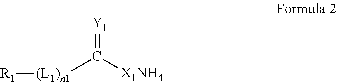
wherein, in Formula 2,
X₁ and Y₁ are each independently O or S,
L₁ is a single bond, a cyclic group having 2 to 10 carbon atoms unsubstituted or substituted with at least one R₀, *—C(R₁₁)(R₁₂)—**′, *—C(═O)—**′, *—C(═S)—**′, *—N(R₁₁)—**′, *—O—**′ or *—S—**′,
n1 is an integer from 1 to 50,
when n1 is 2 or more, two or more of L₁ are the same or different from each other,
R₁, R₁₁, R₁₂ and R₀ are each independently:
hydrogen, deuterium, *—F, *—Cl, *—Br, *—I, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), *—NH—C(═S)—(NH₂), *—ONH₄, *˜SNH₄, *—C(═O)—ONH₄, *—C(═S)—ONH₄, *—C(═O)˜SNH₄, or *—C(═S)˜SNH₄; or
a C₁-C₂₀ alkyl group, a C₂-C₂₀ alkenyl group, a C₁-C₂₀ alkoxy group, a C₆-C₂₀ aryl group, or a C₂-C₂₀ heteroaryl group, each unsubstituted or substituted with deuterium, *—F, *—Cl, *—Br, *—I, *—OH, *—SH, *—NH₂, *—C(═O) H, *—C(═S)H, *—C(═O)—OH, *—C(═S)—OH, *—C(═O)—SH, *—C(═S)—SH, *—C(═O)—(NH₂), *—C(═S)—(NH₂), *—NH—C(═O)—(NH₂), *—NH—C(═S)—(NH₂), *—ONH₄, *˜SNH₄, *—C(═O)—ONH₄, *—C(═S)—ONH₄, *—C(═O)˜SNH₄, *—C(═S)˜SNH₄, or any combination thereof,
when a second carbon directly bonded to a first carbon to which a hydroxyl group is bonded exists in Formula 2, a hydroxyl group (*—OH) and a thiol group (*—SH) are not bonded to the second carbon, and
when a fourth carbon directly bonded to a third carbon to which a thiol group is bonded exists in Formula 2, a hydroxyl group (*—OH) and a thiol group (*—SH) are not bonded to the fourth carbon.

14. The etching composition of claim 1, wherein
an amount of the ammonium salt is 0.5 wt % to 20 wt %, based on 100 wt % of the etching composition.

15. The etching composition of claim 1, wherein
the ammonium salt includes two or more different compounds of compounds having a structure in which at least one of the hydrogen ions (H⁺) of a hydroxyl group (*—OH) or a thiol group (*—SH) included in the accelerator is substituted with an ammonium cation (NH₄⁺).

16. A method of etching a metal-containing layer, the method comprising:
preparing a substrate including a metal-containing layer thereon; and
performing an etching process on the metal-containing layer by using the etching composition of claim 1 to remove at least a portion of the metal-containing layer.

17. The method of claim 16, wherein
the metal-containing layer includes indium (In), titanium (Ti), aluminum (Al), tungsten (W), lanthanum (La), scandium (Sc), gallium (Ga), zinc (Zn), hafnium (Hf), molybdenum (Mo), or any combination thereof.

18. The method of claim 16, wherein
the metal-containing layer includes a first region and a second region,
the performing the etching process on the metal-containing layer includes etching at least a portion of the first region of the metal-containing layer at a first etch rate using the etching composition and etching at least a portion of the second region of the metal-containing layer at a second etch rate using the etching composition, and
the second etch rate is greater than the first etch rate.

19. The method of claim 18, wherein
the first region includes aluminum oxide, and
the second region includes titanium nitride (TiN), titanium nitride further including aluminum (TiAlN), or any combination thereof.

20. A method of manufacturing a semiconductor device, the method comprising:
preparing a substrate including a metal-containing layer thereon;
performing an etching process on the metal-containing layer using the etching composition of claim 1, the etching process removing at least a portion of the metal-containing layer; and
performing one or more subsequent manufacturing processes to manufacture the semiconductor device.
